(19) United States
(12) Patent Application Publication
(10) Pub. No.: US 2017/0077227 A1
(43) Pub. Date: Mar. 16, 2017

(54) Needle Field Plate MOSFET with Mesa Contacts and Conductive Posts

(71) Applicant: Infineon Technologies Austria AG, Villach (AT)

(72) Inventors: David Laforet, Villach (AT); Li Juin Yip, Villach (AT); Cedric Ouvrard, Villach (AT)

(21) Appl. No.: 14/851,855

(22) Filed: Sep. 11, 2015

(51) Int. Cl. H01L 29/06; H01L 29/66; H01L 29/40; H01L 29/78; H01L 29/423

(52) U.S. Cl. CPC H01L 29/0692; H01L 29/7813; H01L 29/4236; H01L 29/407; H01L 29/404; H01L 29/66734

(57) ABSTRACT

There are disclosed herein various implementations of a vertical metal-oxide-semiconductor field-effect transistor (MOSFET). Such a vertical MOSFET includes a semiconductor substrate having a drift region situated over a drain, a gate trench and needle field plates extending into the drift region, and source regions situated in respective mesas. In addition, the vertical MOSFET includes mesa contacts having a first width and extending through a first pre-metal dielectric layer to make electrical contact with the mesas. A second pre-metal dielectric layer is situated over the first pre-metal dielectric layer and the mesa contacts. The vertical MOSFET further includes conductive posts having a second width less than the first width and extending through the second pre-metal dielectric layer to make electrical contact with the mesa contacts.

### BACKGROUND

In a needle field plate metal-oxide-semiconductor field-effect transistor (MOSFET) utilizing a grid gate layout, both the mesa and the needle field plate are coupled to the same electrical contact. However, in order to make contact with the mesa as well as the needle field plate, the width of the electrical contact must be greater than the width or diameter of the needle field plate, which can be as large as several micrometers for high voltage devices.

As a result, the use of a conventional contact fabrication process flow requires that a relatively wide and deep void be patterned in a pre-metal dielectric for each electrical contact. It is important that these voids be substantially completeley filled with a contact metal, because the contact metal typically undergoes subsequent lithographic patterning. However, forming such large contact bodies over the field plates and mesas can result in stress related reliability problems for the needle field plate device. Moreover, underfilling of the voids typically can undesirably reduce the depth of focus (DOF) process window for the subsequent lithography, as well as undesirabley reduce the dry anisotropic etch process window due to thinner resist over the contacts.

### SUMMARY

The present disclosure is directed to a needle field plate metal-oxide-semiconductor field-effect transistor (MOSFET) with mesa contacts and conductive posts, substantially as shown in and/or described in connection with at least one of the figures, and as set forth in the claims.

### BRIEF DESCRIPTION OF THE DRAWINGS

FIG. 1 is a flowchart showing an exemplary method for fabricating a needle field plate metal-oxide-semiconductor field-effect transistor (MOSFET) including mesa contacts and conductive posts, according to one implementation.

FIG. 2A shows a cross-sectional view, which includes a portion of a semiconductor substrate processed according to an initial stage of the exemplary method shown by the flowchart in FIG. 1.

FIG. 2B shows a cross-sectional view, which includes a portion of a semiconductor substrate processed according to an intermediate stage of the exemplary method shown by the flowchart in FIG. 1.

FIG. 2C shows a cross-sectional view, which includes a portion of a semiconductor substrate processed according to an intermediate stage of the exemplary method shown by the flowchart in FIG. 1.

FIG. 2D shows a cross-sectional view, which includes a portion of a semiconductor substrate processed according to an intermediate stage of the exemplary method shown by the flowchart in FIG. 1.

FIG. 2E shows a cross-sectional view, which includes a portion of a semiconductor substrate processed according to an intermediate stage of the exemplary method shown by the flowchart in FIG. 1.

FIG. 2F shows a cross-sectional view, which includes a portion of a semiconductor substrate processed according to an intermediate stage of the exemplary method shown by the flowchart in FIG. 1.

FIG. 2G shows a cross-sectional view, which includes a portion of a semiconductor substrate processed according to an intermediate stage of the exemplary method shown by the flowchart in FIG. 1. FIG. 2H shows a cross-sectional view, which includes a portion of a semiconductor substrate processed according to a final stage of the exemplary method shown by the flowchart in FIG. 1.

FIG. 3 shows a top view of a semiconductor substrate having a needle field plate MOSFET fabricated therein, as though seen through metal contacts and pre-metal dielectric layers, according to one implementation.

### DETAILED DESCRIPTION

The following description contains specific information pertaining to implementations in the present disclosure. One skilled in the art will recognize that the present disclosure may be implemented in a manner different from that specifically discussed herein. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

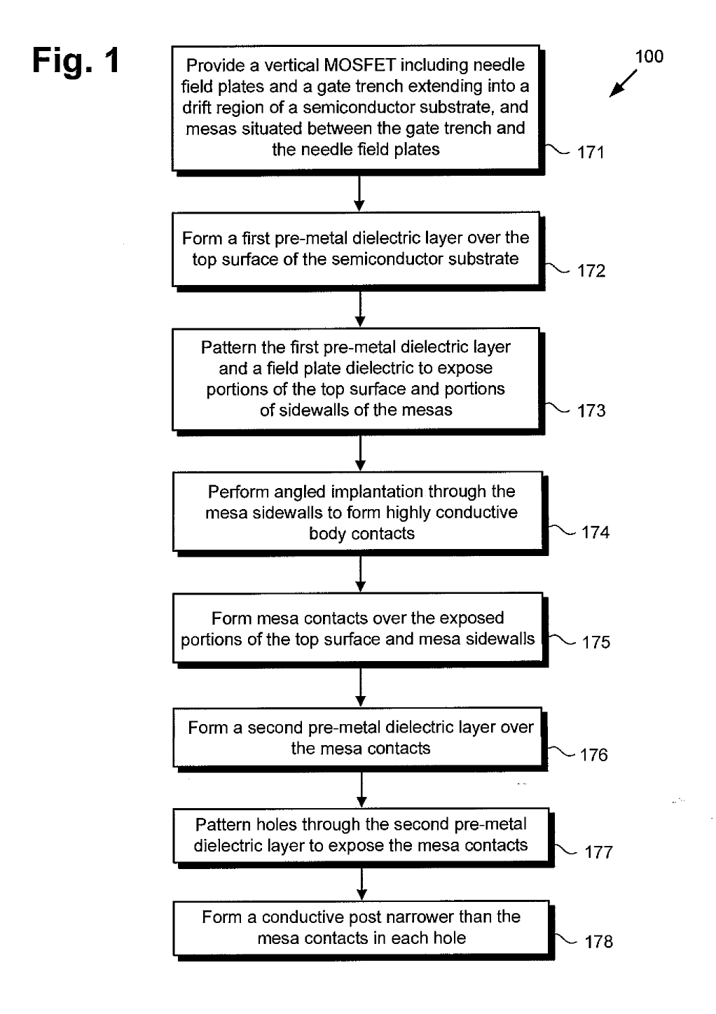

FIG. 1 is a flowchart showing an exemplary method for fabricating a needle field plate metal-oxide-semiconductor field-effect transistor (MOSFET) including mesa contacts and conductive posts, according to one implementation. It is noted that certain details and features have been left out of flowchart 100 that are apparent to a person of ordinary skill in the art. For example, the process flow described by flowchart 100 may involve specialized equipment or materials, as known in the art. Although the process flow indicated in flowchart 100 is sufficient to describe one implementation of the present inventive principles, in other implementations, a method for fabricating a needle field plate MOSFET according to the present concepts may utilize actions different from those shown in flowchart 100, and may include more, or fewer, actions.

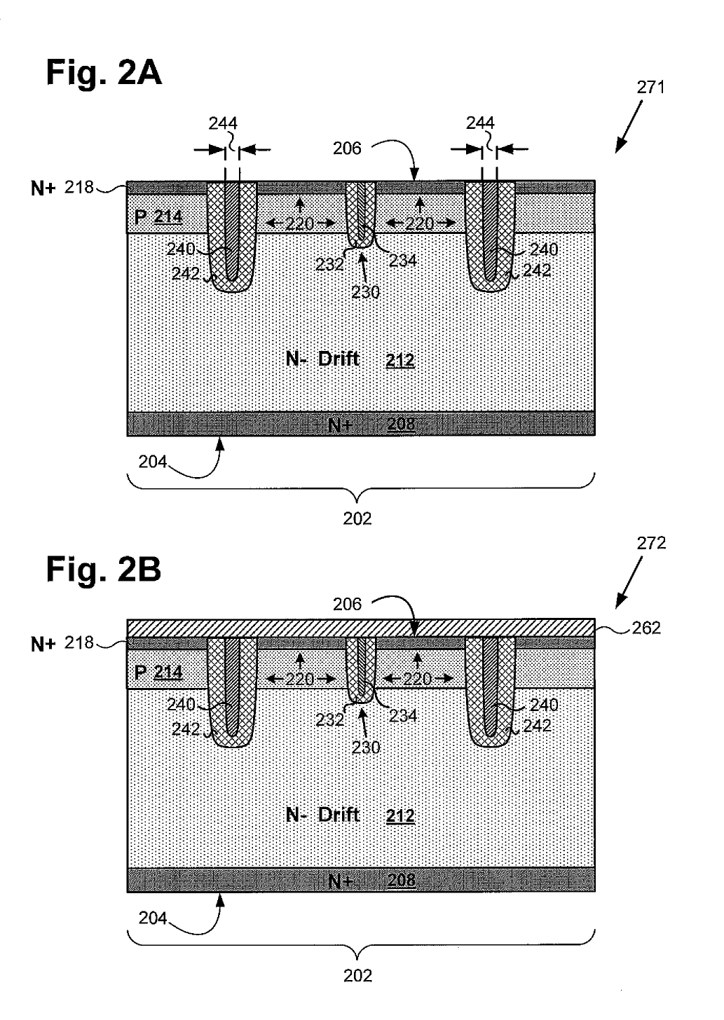

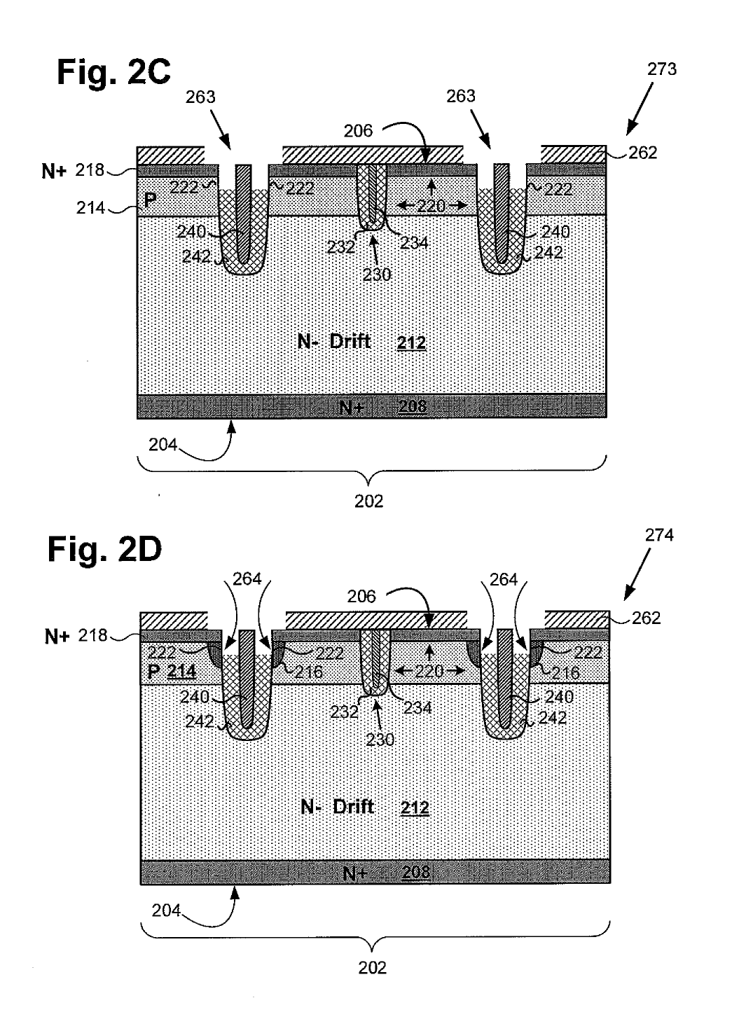

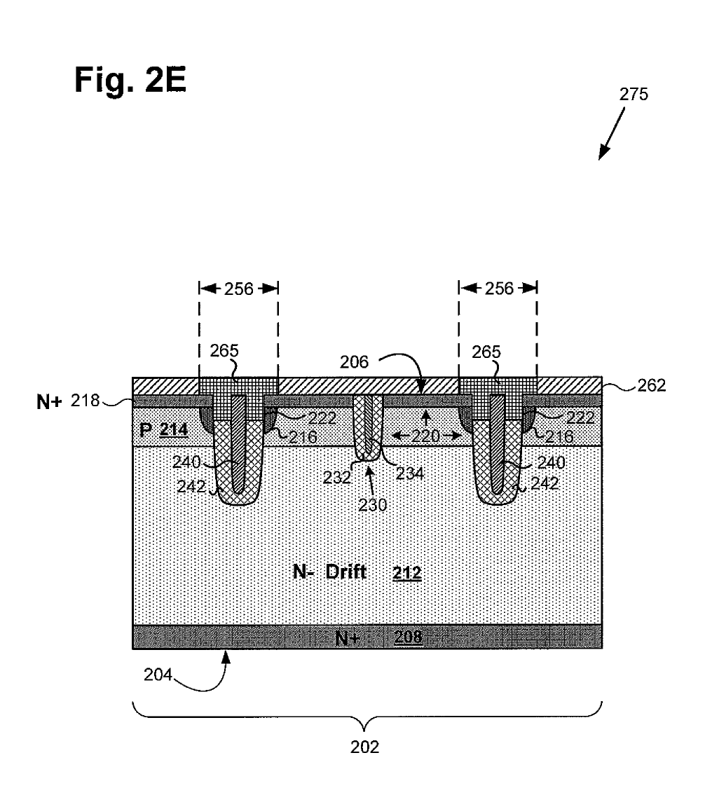

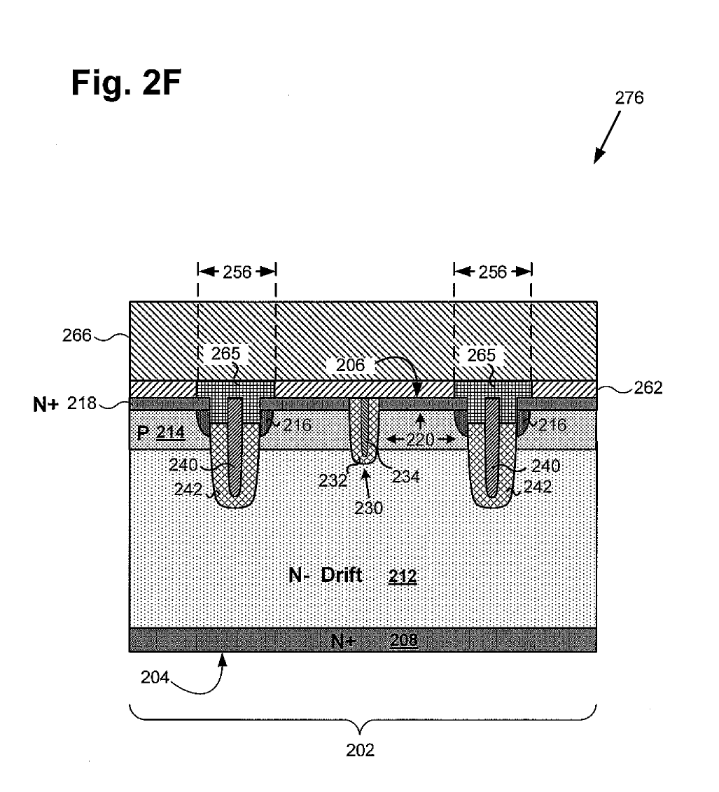

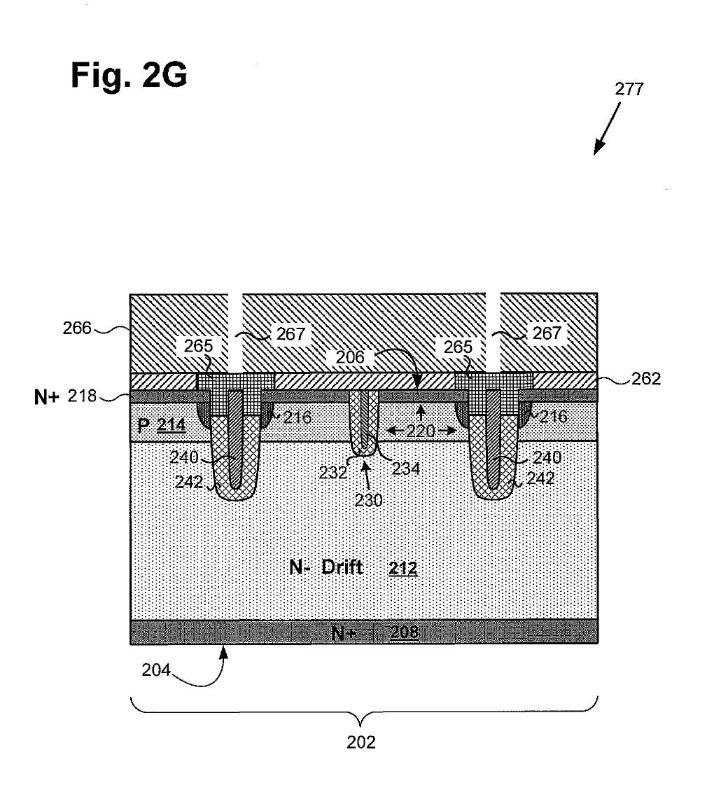

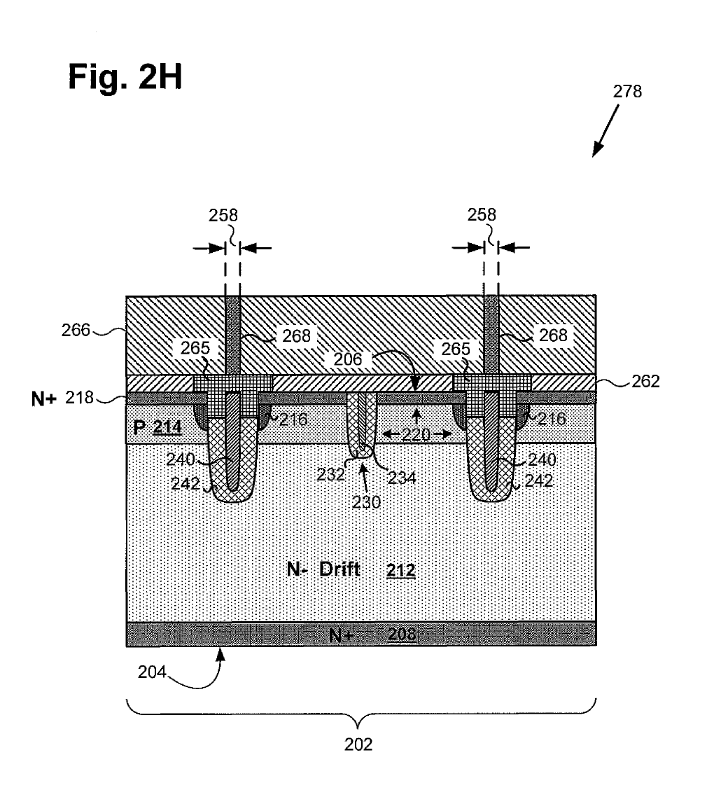

Needle field plate MOSFET structures 271 through 278, shown respectively in FIGS. 2A through 2H, illustrate the result of performing actions 171 through 178 of flowchart 100, respectively. For example, FIG. 2A shows needle field plate MOSFET 271 prior to performance of action 172, FIG. 2B shows needle field plate MOSFET 272 after performance of action 172, FIG. 2C shows needle field plate MOSFET 273 after performance of action 173, FIG. 2D shows needle field plate MOSFET 274 after performance of action 174, and so forth.

Referring to FIG. 1, flowchart 100 begins with providing a vertical MOSFET including needle field plates and a gate trench extending into a drift region of a semiconductor substrate, and mesas situated between the gate trench and the needle field plates (action 171). Referring to FIG. 2A, FIG. 2A shows a cross-sectional view of one exemplary implementation of such a vertical MOSFET as needle field plate MOSFET 271.

As shown in FIG. 2A, needle field plate MOSFET 271 includes highly doped N type drain 208 at bottom surface 204 of semiconductor substrate 202, and N type drift region 212 situated over N type drain 208. In addition, needle field plate MOSFET 271 includes field plates in the form of needle field plates 240, and gate trench 230 including gate dielectric 232 and gate electrode 234, as well as mesas 220 situated between gate trench 230 and needle field plates 240. Mesas 220 include highly doped N type source regions 218 and P type body regions 214 situated under highly doped N type source regions 218.

As further shown in FIG. 2A, needle field plates 240 and gate trench 230 extend from top surface 206 of semiconductor substrate 202, through highly doped N type source regions 218 and P type body regions 214, and into N type drift region 212. Also shown in FIG. 2A are field plate dielectric 242 and diameter 244 of needle field plate 240.

It is noted that although the implementation shown in FIG. 2A depicts needle field plate MOSFET 271 as an n-channel device having N type drain 208, N type drift region 212, P type body regions 214, and N type source regions 218, that representation is merely exemplary. In other implementations, the described polarities can be reversed such that needle field plate MOSFET 271 may be a p-channel device having a P type drain, a P type drift region, N type body regions, and P type source regions.

Semiconductor substrate 202 may be a silicon (Si) substrate or a silicon carbide (SiC) substrate, for example. In some implementations, semiconductor substrate 202 may include N type drift region 212 and mesas 220 formed in an epitaxial silicon layer of semiconductor substrate 202. Formation of such an epitaxial silicon layer may be performed by any suitable method, as known in the art, such as chemical vapor deposition (CVD) or molecular beam epitaxy (MBE), for example. More generally, however, N type drift region 212 and mesas 220 may be formed in any suitable elemental or compound semiconductor layer included in semiconductor substrate 202.

Thus, in other implementations, N type drift region 212 and mesas 220 need not be formed through epitaxial growth, and/or need not be formed of silicon. For example, in one alternative implementation, N type drift region 212 and mesas 220 can be formed in a float zone silicon layer of semiconductor substrate 202. In other implementations, N type drift region 212 and mesas 220 can be formed in either a strained or unstained germanium layer formed as part of semiconductor substrate 202.

P type body regions 214 may be formed by implantation and thermal diffusion. For example, boron (B) dopants may be implanted into semiconductor substrate 202 and diffused to form P type body regions 214. Highly doped N type source regions 218 may be analogously formed by implantation and thermal diffusion of a suitable N type dopant in semiconductor substrate 202. Such a suitable N type dopant may include arsenic (As) or phosphorous (P), for example.

Gate dielectric 232 and field plate dielectric 242 may be formed using any material and any technique typically employed in the art. For example, gate dielectric 232 and field plate dielectric 242 may be formed of silicon dioxide (SiO₂), and may be deposited or thermally grown to produce gate dielectric 232 and field plate dielectric 242. Gate electrode 234 and needle field plates 240 may also be formed using any electrically conductive material typically utilized in the art. For example, gate electrode 234 and needle field plates 240 may be formed of doped polysilicon or metal. It is noted that needle field plates 240 are implemented as long, narrow conductive cylinders. For example, needle field plates 240 may be conductive cylinders having diameter 244 in a range from approximately one micrometer (1.0 μm) to approximately five micrometers (5.0 μm).

Referring to FIG. 1 in combination with needle field plate MOSFET 272, in FIG. 2B, flowchart 100 continues with forming first pre-metal dielectric layer 262 over top surface 206 of semiconductor substrate 202 (action 172). First pre-metal dielectric layer 262 may be formed through deposition of a blanket layer of SiO₂, for example, over top surface 206 of semiconductor substrate 202. First pre-metal dielectric layer 262 may be formed as a relatively thin layer, such as a layer having a thickness over top surface 206 of semiconductor substrate 202 of approximately one hundred nanometers (100 nm).

Referring now to needle field plate MOSFET 273, in FIG. 2C, flowchart 100 continues with patterning first pre-metal dielectric layer 262 and field plate dielectric 242 to expose portions of top surface 206 and portions of sidewalls 222 of mesas 220 (action 173). Patterning of first pre-metal dielectric layer 262 and field plate dielectric 242 may be performed using a contact lithographic process, for example. During the patterning process, which can include a masking stage and an etch stage, a portion of first pre-metal dielectric layer 262 and a corresponding portion of field plate dielectric 242 can be removed to expose regions 263 including portions of top surface 206 and mesa sidewalls 222.

Referring to needle field plate MOSFET 274, in FIG. 2D, flowchart 100 continues with performing angled implantation 264 through mesa sidewalls 222 to from highly conductive P type body contacts 216 (action 174). Highly conductive P type body contacts 216 may be more highly doped areas within P type body regions 214 utilizing the same dopant species used to form P type body regions 214, such as B, for example.

It is noted that several advantages accrue from performing angled implantation 264 through mesa sidewalls 222. For example, because angled implantation 264 through mesa sidewalls 222 enhances control over the location and dimensions of highly conductive P type body contacts 216, the present method enables substantially optimal placement of highly conductive P type body contacts 216 relative to gate trench 230. As a result, and particularly for lower voltage and small geometry devices, well controlled placement of highly conductive P type body contacts 216 can substantially minimize the effect of highly conductive P type body contacts 216 on threshold voltage variation. Moreover, the well controlled placement of highly conductive P type body contacts 216 resulting from angled implantation 264 through mesa sidewalls 222 enables formation of highly conductive P type body contacts 216 without significant counter doping of pre-existing highly doped N type source regions 218.

Referring to needle field plate MOSFET 275, in FIG. 2E, flowchart 100 continues with forming mesa contacts 265 over the exposed portions of top surface 206 and mesa sidewalls 222 (action 175). Mesa contacts 265 may be formed of any conductive material capable of forming a good ohmic contact with needle field plates 240, as well as highly doped N type source regions 218 and highly conductive P type body contacts 216 of mesas 220. For example, mesa contacts 265 may be formed of doped polysilicon, a metal, a metal alloy, or a metal stack such as a titianium/titanium nitride/tungsten (Ti/TiN/W) metal stack.

Mesa contacts 265 may be formed through deposition of a blanket layer of a suitable conductive material over first pre-metal dielectric layer 262, resulting in regions 263 being filled by the conductive material. Although not explicitly shown in the present figures, such a deposition process may be followed by removal of the conductive material from over first pre-metal dielectric layer 262. For example, a chemical-mechanical planarization (CMP) process stopping at first pre-metal dielectric layer 262 may be used to remove excess portions of the conductive material used to form mesa contacts 265.

As shown in FIG. 2E, the resulting mesa contacts 265 are substantially coplanar with first pre-metal dielectric layer 262, have width 256, and extend through first pre-metal dielectric layer 262 to make electrical contact with mesas 220 and needle field plates 240. As further shown in FIG. 2E, highly conductive P type body contacts 216 adjoin mesa contacts 265 at mesa sidewalls 222.

Referring now to needle field plate MOSFET 276 FIG. 2F, flowchart 100 continues with forming second pre-metal dielectric layer 266 over first pre-metal dielectric layer 262 and mesa contacts 265 (action 176). Second pre-metal dielectic layer 266 is substantially thicker than first pre-metal dielectric layer 262, and may be formed of the same dielectric material used to form first pre-metal dielectric layer 262, or may be formed of a different dielectric material. For example second pre-metal dielectric layer 266 may be a borophosphosilicate glass (BPSG) layer, formed over first pre-metal dielectric layer 262 and mesa contacts 265 to a thickness in a range from approximately 1.4 μm to approximately 2.4 μm. In other words, the thickness of the dielectric stack formed by first pre-metal dielectric layer 262 and second pre-metal dielectric layer 266 may be in a range from approximately 1.5 μm to approximately 2.5 μm.

Referring to needle field plate MOSFET 277, in FIG. 2G, flowchart 100 continues with patterning holes 267 through second pre-metal dielectric layer 266 to expose mesa contacts 265 (action 177). Patterning of holes 267 through second pre-metal dielectric layer 266 may be performed using a contact lithographic process, for example. During the patterning process, which can include a masking stage and an etch stage, a portion of second pre-metal dielectric layer 266 corresponding to holes 267 can be removed to expose mesa contacts 265.

Referring to needle field plate MOSFET 278, in FIG. 2H, flowchart 100 can conclude with forming conductive posts 268 having width 258 less than width 256 of mesa contacts 265 (action 178). Conductive posts may be formed of any conductive material capable of forming a good ohmic contact with mesa contacts 220. Moreover, conductive posts 268 may be formed of the same conductive material used to form mesa contacts 265, or may be formed of a different conductive material. For example, conductive posts 268 may be formed of doped polysilicon, a metal such as W or copper (Cu), a metal alloy, or a metal stack such as a Ti/TiN/W metal stack. As shown in FIG. 2H, conductive posts 268 extend through second pre-metal dielectric layer 266 to make electrical contact with mesas contacts 265.

It is noted that although width 258 of conductive posts 268 is depicted as being substantially less than width 256 of mesa contacts 265, that representation is merely by way of example. The only limitation placed on the relative widths of conductive posts 268 and mesa contacts 265 is that width 258 of conductive posts 268 be less than width 256 of mesa contacts 265. In some implementatios, width 258 of conductive posts 268 may be substantially similar to diameter 244 of needle field plate 240 shown in FIG. 2A, thereby resulting in conductive posts 268 being substantially narrower than mesa contacts 265. However, in other implementations, it may be advantageous or desirable for width 258 of conductive posts 268 to approach width 256 of mesa contacts 265. It is further noted that according to the implementations disclosed in the present application, needle field plate MOSFET 278 may be a silicon or other group IV based power transistor having a voltage rating in a range from approximately sixty volts (60 V) to approximately four hundred volts (400 V), for example.

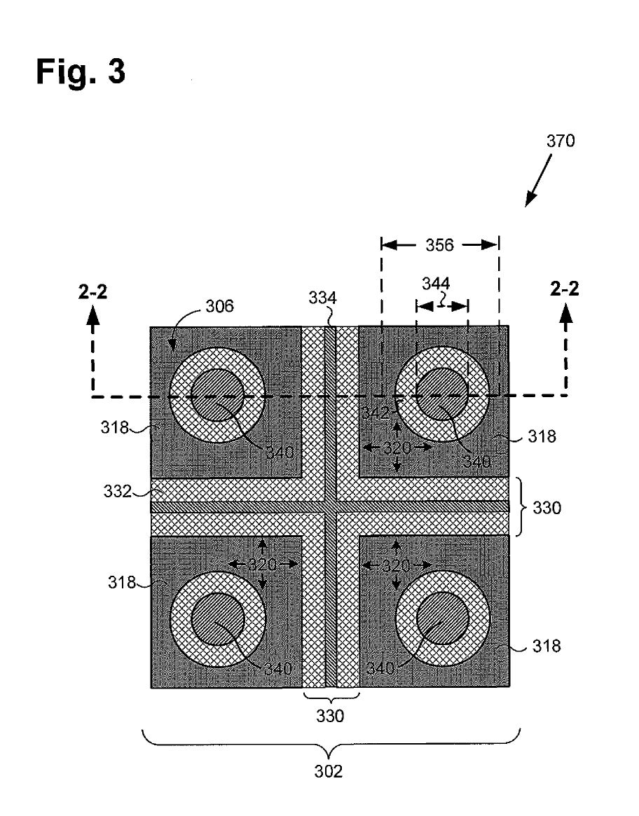

Moving to FIG. 3, FIG. 3 shows a top view of needle field plate MOSFET 370, as though seen through metal contacts and pre-metal dielectric layers, according to one implementation. Needle field plate MOSFET 370 includes substrate 302 having top surface 306. In addition, FIG. 3 shows mesas 320 of substrate 302 including highly doped N type source regions 318, gate trenches 330 including gate dielectric 332 and gate electrode 334, and needle field plates 340. Also shown in FIG. 3 are field plate dielectric 342, needle field plate diameter 344, width 356, and perspective lines 2-2.

Needle field plate MOSFET 370 corresponds in general to all of needle field plate MOSFETs 271-278 in respective FIGS. 2A-2H, as though seen from above and seen through conductive posts 268, second pre-metal dielectric layer 266, mesa contacts 265, and first pre-metal dielectric layer 262. In other words, substrate 302, mesas 320 including highly doped source regions 318, and gate trenches 330 correspond respectively to substrate 202, mesas 220 including highly doped source regions 218, and gate trench 230 in FIGS. 2A-2H and may share any of the characteristics attributed to those corresponding features above.

In addition, needle field plates 340 having diameter 344, field plate dielectric 342, and width 356, in FIG. 3, correspond respectively to needle field plates 240 having diameter 244, field plate dielectric 242, and width 256 of mesa contacts 265, in FIGS. 2A-2H and may share any of the characteristics attributed to those corresponding features above. Moreover, it is noted that FIGS. 2A-2H show cross-sections of needle field plate MOSFET 370 viewed along perspective lines 2-2 in FIG. 3.

As shown in FIG. 3, in contrast to gate electrodes 334, which are shown as extended trench electrodes, needle field plates 340 are implemented as conductive cylinders having diameter 344. As further shown in FIG. 3, width 356 of mesa contacts corresponding to mesa contacts 265 in FIGS. 2D-2H must be greater than diameter 344 in order to concurrently make contact with needle field plate 340 and mesas 320.

Thus, the present application discloses implementations of a needle field plate MOSFET with mesa contacts and conductive posts. By patterning a thin first pre-metal dielectric layer formed over a semiconductor substrate to expose portions of a top surface of the substrate and portions of sidewalls of mesas of the substrate, the present solution advantageously enables performance of angled dopant implantation through the mesa sidewalls. As a result, the location of highly conductive body contacts formed in the substrate can be well controlled, enhancing stability and performance of the needle field plate MOSFET. In addition, use of mesa contacts extending through the first pre-metal dielectric layer enables use of the mesa contacts as a single contact body capable of making electrical contact with the mesas and the needle field plates concurrently. Moreover, use of conductive posts narrower than the mesa contacts to extend through a second pre-metal dielectric layer to make electrical contact with the mesa contacts further enhances device performance.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described herein, but many rearrangements, modifications, and substitutions are possible without departing from the scope of the present disclosure.

1. A vertical metal-oxide-semiconductor field-effect transistor (MOSFET) comprising:
a semiconductor substrate having a drift region situated over a drain, a gate trench and needle field plates extending into said drift region, and source regions situated in respective mesas;
mesa contacts having a first width and extending through a first pre-metal dielectric layer to make electrical contact with said mesas;
a second pre-metal dielectric layer situated over said first pre-metal dielectric layer and said mesa contacts;
conductive posts having a second width less than said first width and extending through said second pre-metal dielectric layer to make electrical contact with said mesa contacts.

2. The vertical MOSFET of claim 1, wherein each of said mesas includes a body region situated under said source regions.

3. The vertical MOSFET of claim 1, wherein said needle field plate comprises a conductive cylinder.

4. The vertical MOSFET of claim 1, wherein each of said mesas includes a body region having a highly conductive body contact adjoining a respective one of said mesa contacts.

5. The vertical MOSFET of claim 4, wherein said highly conductive body contact is formed using an angled implantation through a sidewall of said respective mesas.

6. The vertical MOSFET of claim 5, wherein said angled implantation does not result in counter doping of said source regions.

7. The vertical MOSFET of claim 1, wherein said vertical MOSFET is an re-channel FET.

8. The vertical MOSFET of claim 1, wherein said vertical MOSFET is a p-channel FET.

9. The vertical MOSFET of claim 1, wherein said semiconductor substrate comprises at least one of silicon and silicon carbide.

10. The vertical MOSFET of claim 1, wherein said vertical MOSFET is a power transistor having a voltage rating in a range from approximately 60 V to approximately 400 V.

11. A method for fabricating a vertical metal-oxide-semiconductor field-effect transistor (MOSFET), said method comprising:
providing a semiconductor substrate having a drift region situated over a drain, a gate trench and needle field plates extending into said drift region, and source regions situated in respective mesas;
forming a first pre-metal dielectric layer over said semiconductor substrate;
forming mesa contacts having a first width and extending through said first pre-metal dielectric layer to make electrical contact with said mesas;
forming a second pre-metal dielectric layer over said first pre-metal dielectric layer and said mesa contacts;
forming conductive posts having a second width less than said first width and extending through said second pre-metal dielectric layer to make electrical contact with said mesa contacts.

12. The method of claim 11, wherein each of said mesas includes a body region situated under said source regions.

13. The method of claim 11, wherein said needle field plate comprises a conductive cylinder.

14. The method of claim 11, further comprising patterning said first pre-metal dielectric layer and a field plate dielectric interposed between said needle field plate and said substrate to expose portions of said top surface and portions of sidewalls of said mesas.

15. The method of claim 14, further comprising performing an angled implantation through said sidewalls of said mesas to form a highly conductive body contact within a body region of each of said mesas prior to forming said mesa contacts.

16. The method of claim 15, wherein said angled implantation does not result in counter doping of said source regions.

17. The method of claim 11, wherein said vertical MOSFET is an n-channel FET.

18. The method of claim 11, wherein said vertical MOSFET is a p-channel FET.

19. The method of claim 11, wherein said semiconductor substrate comprises at least one of silicon and silicon carbide.

20. The method of claim 11, wherein said vertical MOSFET is a power transistor having a voltage rating in a range from approximately 60 V to approximately 400 V.
